(19) United States
(12) Patent Application Publication
(10) Pub. No.: US 2012/0062339 A1
(43) Pub. Date: Mar. 15, 2012

(54) MEMS NOTCH FILTER AND METHOD

(76) Inventor: Alan S. Edelstein, Alexandria, VA (US)

(21) Appl. No.: 12/343,906

(22) Filed: Dec. 24, 2008

(51) Int. Cl. H03H 9/02; H01R 43/00

(52) U.S. Cl. 333/186; 29/825

(57) ABSTRACT

A MEMS notch filter comprises a frame; a movable mass; resilient members connecting the mass to the frame; electrodes connected to the frame; and a comb drive connected to the frame and the mass which operates to drive the mass, wherein the filter is adapted to oscillate at least one resonant frequency. A mechanism is positioned below the mass, wherein the mechanism is adapted to maintain a neutral position of the mass and to expel fluid onto the mass. The comb drive is adapted to receive an applied voltage signal from the electrodes. This voltage signal is applied to the comb drive at a resonant frequency of the notch filter and induces the mass to oscillate in a geometric plane of the frame (or optionally in some other resonant mode); resulting in dissipation of energy and voltage attenuation. Other voltage components not at the notch frequency are not attenuated.

### GOVERNMENT INTEREST

The embodiments described herein may be manufactured, used, and/or licensed by or for the United States Government without the payment of royalties thereon.

### BACKGROUND

1. Technical Field

The embodiments herein generally relate to micro-electromechanical systems (MEMS) and devices and, more particularly, to low frequency filters used with MEMS devices.

2. Description of the Related Art

In signal processing, unwanted signals should be suppressed. One of the most prevalent of these unwanted signals occurs during the pickup of 50 or 60 Hz signals and their harmonics from electrical power lines. This pickup can both mask the desired signal and saturate amplifiers. The conventional methods for coping with this problem generally include a passive LC filter and using zero point crossing filtering. Unfortunately, the limitations of the conventional methods generally include an insufficient quality factor (Q), high cost, and/or increased design complexity. The quality factor, Q, is a function of the ratio of the maximum energy stored in a device and the total energy lost in the device during a given period of time.

Filtering of low frequencies can be performed by a variety of methods and include using zero crossings (i.e., where the reference voltage is zero). Nevertheless, most commercial low frequency filters generally do not have a very high Q and are generally not as effective as one would like in attenuating unwanted signals at particular frequencies such as 60 Hz signals. Accordingly, there remains a need for a novel MEMS filter capable of removing spurious 60 Hz signals and having a high Q.

An example of a MEMS device and a method of manufacturing a MEMS device is disclosed in U.S. Pat. No. 7,185,541 to Edelstein, which issued on Mar. 6, 2007, and which is hereby incorporated by reference as though fully rewritten herein.

### SUMMARY

In view of the foregoing, an embodiment herein provides a MEMS notch filter comprising a switch and a sub-filter operatively connected to the switch, wherein the sub-filter comprises a frame; a movable proof mass; a plurality of resilient members operatively connecting the proof mass to the frame; a plurality of electrodes operatively connected to the frame; and a comb drive operatively connected to the frame and the proof mass, wherein the sub-filter is adapted to oscillate at a single resonant frequency. Preferably, the MEMS notch filter further comprises a mechanism positioned below the proof mass, wherein the mechanism is adapted to maintain a neutral position of the proof mass, and wherein the mechanism comprises a fluid dispenser adapted to expel fluid onto the proof mass. The flow of fluid can be used to balance the weight of the proof mass.

The comb drive is preferably adapted to receive an applied voltage signal from the electrodes. This voltage signal is preferably applied to the comb drive and includes a component at a resonant frequency of the sub-filter and induces the proof mass to oscillate in a geometric plane of the frame. Additionally, oscillation of the proof mass preferably causes a dissipation of energy. Moreover, the proof mass preferably comprises a mass of approximately 1.4×10⁻³ g. Furthermore, the resilient members may comprise a spring constant of approximately 200 g/s² and the resonant frequency may approximately be between 48 and 62 Hz.

Another embodiment provides a MEMS device comprising a filter comprising a movable proof mass component; at least one resilient member operatively connected to the movable proof mass component; an electrostatic comb drive operatively connected to the movable proof mass component; and an electrode operatively connected to any of the electrostatic comb drive and the movable proof mass component, wherein the filter is adapted to oscillate at a single resonant frequency caused by the proof mass and the at least one resilient member. The MEMS device further comprises a mechanism positioned below the proof mass, wherein the mechanism is adapted to maintain a neutral position of the proof mass, and wherein the mechanism comprises a fluid dispenser adapted to expel fluid onto the proof mass.

Preferably, the comb drive is adapted to receive an applied voltage signal from the electrode. This voltage signal is preferably applied to the comb drive at a resonant frequency of the sub-filter and induces the proof mass to oscillate. Additionally, oscillation of the proof mass component preferably causes a dissipation of energy. Preferably, the proof mass component comprises a mass of approximately 1.4×10⁻³ g. Moreover, the resilient members may comprise a spring constant of approximately 200 g/s². Furthermore, the resonant frequency is preferably between 48 and 62 Hz.

Yet another embodiment provides a method of forming a MEMS device, wherein the method comprises operatively connecting an electrical switch to a filter, wherein the filter is formed by configuring a movable proof mass; operatively connecting at least one resilient member to the movable proof mass; operatively connecting an electrostatic comb drive to the movable proof mass; and operatively connecting a plurality of electrodes to any of the electrostatic comb drive and the movable proof mass, wherein the filter is adapted to oscillate at a single resonant frequency with the introduction of an electrical signal on the electrodes at a correct frequency. The method may further comprise positioning a mechanism below the proof mass, wherein the mechanism is adapted to maintain a neutral position of the proof mass, and wherein the mechanism comprises a fluid dispenser adapted to expel fluid onto the proof mass.

Preferably, the comb drive is adapted to receive an applied voltage signal from the electrodes. This voltage signal is preferably applied to the comb drive at a resonant frequency of the sub-filter and induces the proof mass to oscillate. Additionally, oscillation of the proof mass preferably causes a dissipation of energy. Moreover, the proof mass may comprise a mass of approximately 1.4×10⁻³ g. Furthermore, the resilient members may comprise a spring constant of approximately 200 g/s². Also, the resonant frequency is preferably between approximately 48 and 62 Hz.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE DRAWINGS

The embodiments herein will be better understood from the following detailed description with reference to the drawings, in which:

FIG. 1 illustrates a schematic diagram of a filter according to an embodiment herein;

FIG. 2 illustrates a detailed schematic diagram of the filter of FIG. 1 according to an embodiment herein;

FIG. 3(A) illustrates a top view of the sub-filter of FIG. 2 according to an embodiment herein;

FIG. 3(B) illustrates a cross-sectional view of the sub-filter of FIG. 3(A) taken along cut line A-A in FIG. 3(A) according to an embodiment herein; and

FIG. 4 is a flow diagram illustrating a preferred method according to an embodiment herein.

### DETAILED DESCRIPTION OF PREFERRED EMBODIMENTS

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

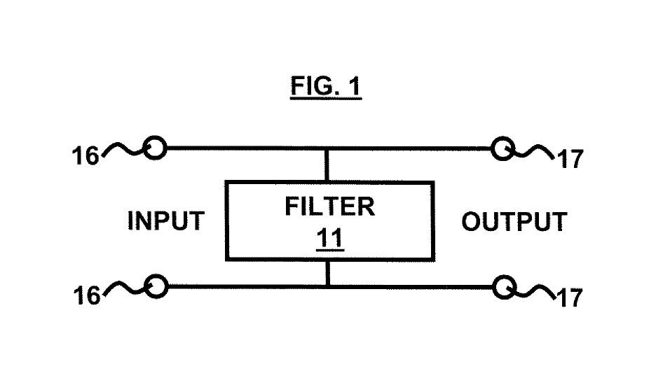

As mentioned, there remains a need for a filter capable of removing spurious 60 Hz signals and having a high Q. The embodiments herein achieve this by providing a novel, nearly passive, low cost, high Q MEMS filter. Referring now to the drawings, and more particularly to FIGS. 1 through 4, where similar reference characters denote corresponding features consistently throughout the figures, there are shown preferred embodiments.

FIG. 1 shows an overview of a filter 11 in accordance with an embodiment herein, in which the filter 11 comprises an input and an output port, and is shown in parallel with a load (not shown) connectable across the output port. The filter 11 decreases the amplitude of a voltage at the notch frequency. This is accomplished by applying the voltage at the input electrodes 16 and then recovering the modified voltage at the output electrodes 17. When the frequency of the signal applied to the input electrodes 16 is not at the notch frequency, 60 Hz, the filter 11 has sufficiently high impedance such that the output signal is not affected by the notch filter 11 and the output voltage is equal to the input voltage. When the signal applied to the input electrodes 16 contains a component that is equal to the notch frequency, the impedance of the notch frequency is much lower, and the component current at that frequency flows through the notch filter 11 and that component of voltage is attenuated because of the energy loss in the filter 11.

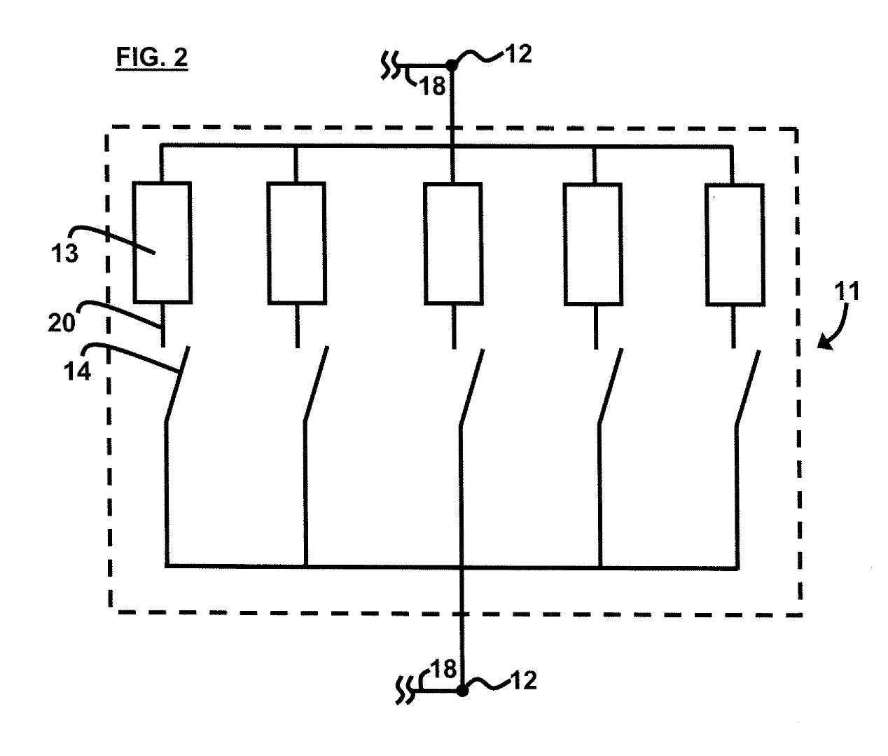

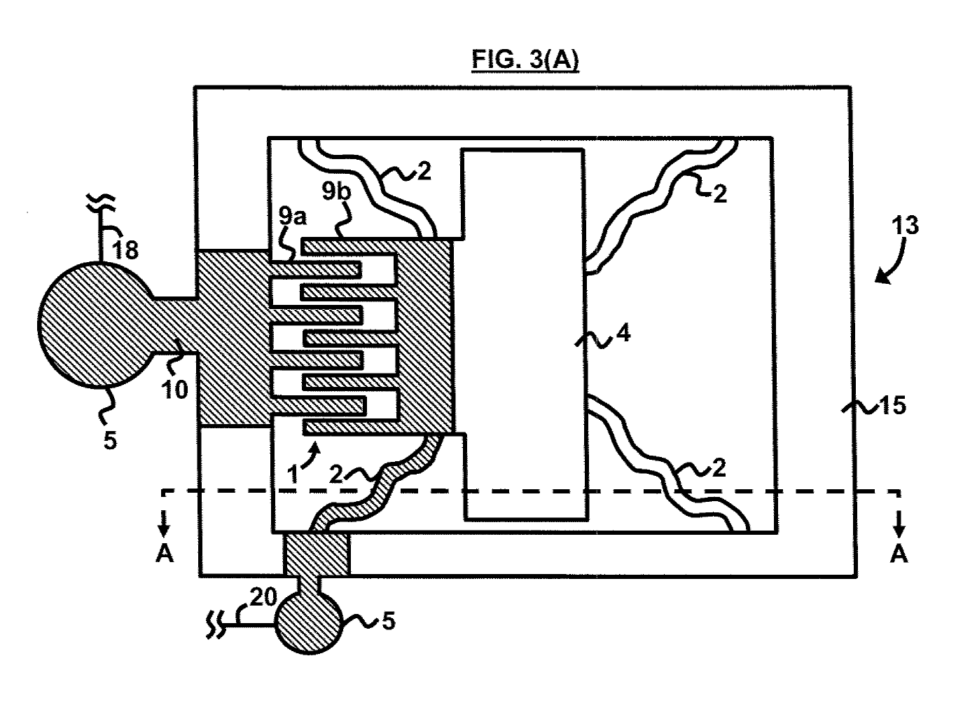

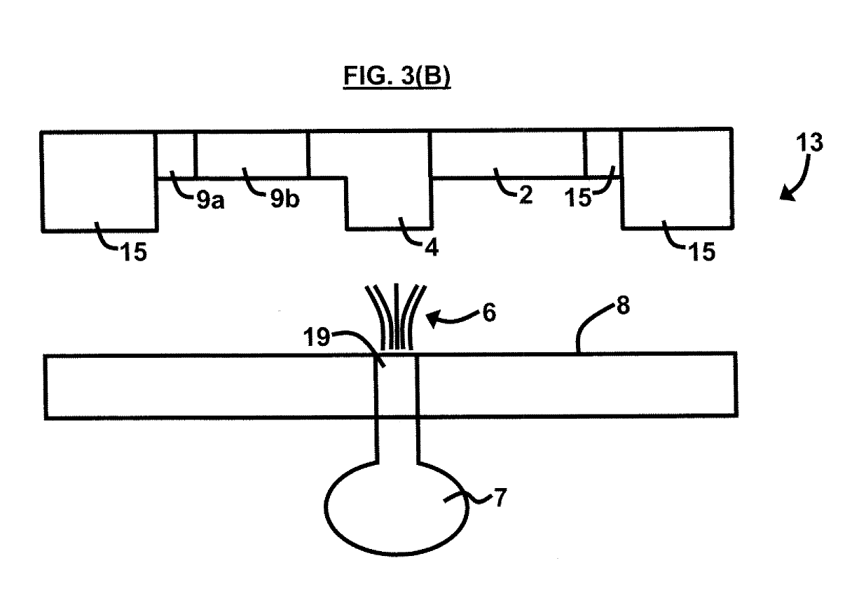

FIG. 2 shows the filter 11 in more detail. The electrodes 12 connect the filter 11 to the rest of the circuit (not shown). Moreover, electrodes 12 of FIG. 2 connect to electrodes 5 (of FIG. 3(A)) via connecting wires 18 and 20. Again with respect to FIG. 2, inside the filter 11 are individual MEMS sub-filters 13 that are added to the circuit if the switches 14 are closed. The switches 14 are electrically operated. For example, the switches 14 could be embodied as MEMS switches and operate due to the bending of piezoelectric (PZT) thin film actuators, and for example, could include require approximately 6-9 volts to operate. The 6-9 volts can be obtained using charge pumps, for example. Many other types of MEMS switches could also be used including electrostatic drives that require approximately 50-90 volts to operate. The operation of these switches are known to those skilled in the art. Multiple sub-filters 13 can be used in accordance with the embodiments herein because they are so small. Each element is preferably on the order of approximately a millimeter in size. Moreover, the individual sub-filters 13 do not play a role in the functionality of the embodiments herein unless a switch 14 in series with a particular sub-filter 13 is closed. FIG. 2 illustrates the case where the switches 14 are open.

A detailed view of one of the MEMS sub-filters 13 is shown in FIGS. 3(A) and 3(B). Generally, the sub-filter 13 comprises a plurality of electrodes 5, an outer frame 15, a relatively large proof mass 4 (further described below), resilient members 2, a MEMS comb drive 1, and a mechanism 7 such as a tank that includes a fluid dispenser 19 for releasing a jet of fluid 6 such as gas. The resilient members 2 may be embodied as a spring or any structure exploiting tension and/or compression of matter. The outer frame 15, resilient members 2, and comb drive 1 can be fabricated out of high impedance, undoped silicon, for example. The resilient members 2 support the weight of the proof mass 4. Resilient members 2 also provide restoring forces that keep the teeth 9a, 9b of the MEMS comb drive 1 from contacting each other and bring the proof mass 4 back to the position it has when no voltage is applied (i.e., neutral position). Electrically conducting paths 10 to the teeth 9a, 9b of MEMS comb drive 1 can be made by depositing gold or some other metallic conductor or by doping selected regions of the outer frame 15, proof mass 4, and, MEMS comb drive 1. The motion of the sub-filter 13 is driven by applying opposite sign voltages to the teeth 9a of the comb drive 1 that are connected to the outer frame 15 and to the teeth 9b of the comb drive 1 that are connected to the proof mass 4. Again, the electrodes 5 shown in FIGS. 3(A) and 3(B) are connected to the electrodes 12 in FIG. 2 via electrically conducting wires 18 and 20. The opposite sign voltages come from applying the voltage source that is to be filtered to the input electrodes 16 shown in FIG. 1.

The amount of energy absorbed at the resonant frequency, fₒ, by the filter 11 is controlled by the number of sub-filters 13 that are in the circuit and the amount of energy each sub-filter 13 absorbs. Individual sub-filters 13 are added or removed from the circuit by closing or opening the switches 14. The sub-filters 13 can be adapted to be at the same frequency if it is desirable to have more attenuation at a single frequency or the sub-filters 13 can be adapted to have different frequencies if it is desirable to be able to attenuate different frequencies. As mentioned above, the switches 14 in FIG. 2 can be configured as MEMS switches whose operation (i.e., opening and closing) is based on the bending of PZT thin film actuators. The amount of energy that each sub-filter 13 absorbs is determined by the energy loss due to the mechanical motion. The energy loss due to the mechanical motion is due to air resistance to the motion and energy losses in the resilient members 2. Larger voltages at the resonant frequency, fₒ, cause large energy losses. A signal at the resonant frequency, fₒ, applied to the comb drive 1 in the sub-filters 13 induces the proof mass 4 to oscillate in the plane of the frame 15 and dissipates energy. The resonant frequency, fₒ, is generally expressed as:

$${f}_{o} = \frac{1}{2 π} \sqrt{k / M}$$

where M is the mass of the proof mass 4 and k is the effective spring constant of all of the resilient members 2.

In order to obtain a low resonant frequency, fₒ, of approximately 50 or 60 Hz it is preferable to get a large proof mass 4 and a very small spring constant k for the resilient members 2. The proof mass 4 is made large by configuring it as the total thickness of a silicon-on-insulator (SOI) wafer. This thickness is approximately 600 microns. Because M/k is large, the gravitational force tends to displace the proof mass 4 out of the plane of the sub-filter 13. If necessary, this tendency can be balanced by having a small flow of fluid 6 that comes up under the center of the proof mass 4. Many kinds of fluids 6, including air, may be used. Moreover, the flow rate of the fluid 6 can be quite modest, for example, on the order of approximately 1-5 ccs per minute. Such a flow maintains a small separation between the proof mass 4 and a generally flat surface 8 underneath the proof mass 4.

Preferably, the size of the proof mass 4 is approximately 100 microns×1000 microns×600 microns and comprises silicon. Accordingly, the mass of the proof mass 4 is approximately 1.4×10⁻³ g. The preferred spring constant for the resilient members 2 at 60 Hz is approximately 200 g/s². For a proof mass 4 supported between two fixed points, k is approximately 192EI/x³. For polysilicon, E is approximately 160 GPa; and I=bh³/12 where b and h are the width and height of a beam (assumed rectangular cross section of the proof mass 4). Here, the quantity x is the total length of the proof mass 4, and the centroid is located at x/2. Taking b=h=2 microns and x=1000 microns, k=42 g/s² for example, thus, it is possible to make resilient members 2 with sufficiently small spring constants.

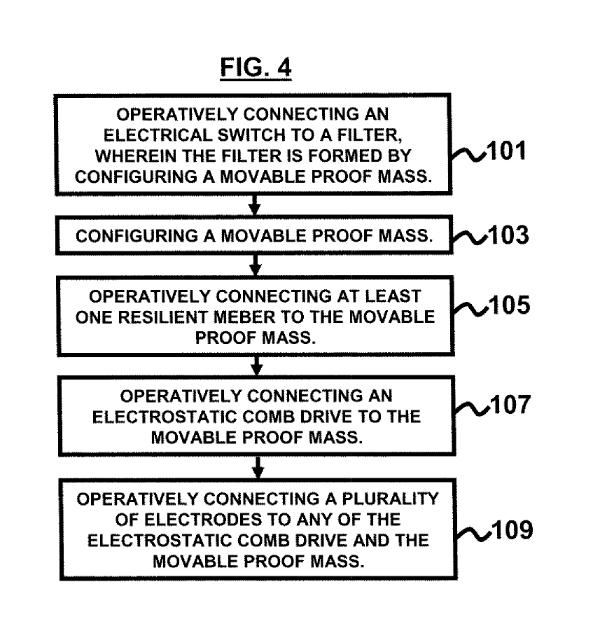

FIG. 4 (with reference to FIGS. 1 through 3(B)) is a flow diagram illustrating a method of forming a MEMS device, wherein the method comprises operatively connecting (101) an electrical switch 14 to a filter 11, wherein the filter 11 is formed by configuring (103) a movable proof mass 4; operatively connecting (105) at least one resilient member 2 to the movable proof mass 4; operatively connecting (107) an electrostatic comb drive 1 to the movable proof mass 4; and operatively connecting (109) a plurality of electrodes 5 to any of the electrostatic comb drive 1 and the movable proof mass 4, wherein the filter 11 is adapted to oscillate at a single resonant frequency with the introduction of an electrical signal on the electrodes 5 at a correct frequency. In operation, an input signal (from a voltage source (not shown)) containing some component of an unwanted signal at frequency, fₒ, is applied to the filter 11. Preferably, the filter 11 is attached in parallel to the output of the voltage source that one wishes to attenuate at the frequency of the filter 11. The filter 11 begins operating as soon as it is connected to the voltage source. The switches 14 are closed to the sub-filters 13 that attenuate at the frequency, fₒ. The component of the signal at the undesired frequency causes the proof mass 4 in the sub-filters 13 to oscillate at the frequency, fₒ. Maintaining this motion requires energy. This energy comes from the component of the unwanted signal, fₒ. Thus, this component of the signal is attenuated.

The method may further comprise positioning a mechanism 7 below the proof mass 4, wherein the mechanism 7 comprises a fluid dispenser 19 and is adapted to expel fluid 6 such as gas onto the proof mass 4. The flow of fluid may be adjusted to support the weight of the proof mass 4. Moreover, the flow of fluid is preferably steady once it is expelled from the fluid dispenser 19. Additionally, the mechanism 7 is adapted to maintain a neutral position of the proof mass 4. The comb drive 1 is preferably adapted to receive an applied voltage signal from the electrodes 5. This voltage signal applied to the comb drive 1 at a resonant frequency of the filter 11 preferably induces the proof mass 4 to oscillate in a geometric plane of the frame 15. Additionally, oscillation of the proof mass 4 preferably causes a dissipation of energy. Moreover, the proof mass 4 may comprise a mass of approximately 1.4×10⁻³ g. Furthermore, the resilient member 2 may comprise a spring constant of approximately 200 g/s². Also, the resonant frequency is preferably between approximately 48 and 62 Hz.

The embodiments herein utilize moving harmonic MEMS devices that oscillate at a harmonic frequency. Because it is a MEMS device, it has a single frequency oscillation and hence a very sharp Q. Moreover, multiple devices can be deployed in parallel to increase the attenuation of the filter 11 (of FIG. 2) at the resonant frequency, fₒ. Generally, the embodiments herein are embodied as a mechanical device such as a notch filter 11. Normally, such an implementation would be impractical; however, the embodiments herein are able to provide such a solution because the size and cost of MEMS devices can be built to work at low frequencies such as 60 Hz. Comb drives are used extensively in MEMS devices. Applying a voltage to the teeth 9a, 9b of the comb drive 1 gives rise to electric fields that tend to increase the overlap of the teeth 9a, 9b of the comb drive 1.

The term notch filter as used herein includes a band-stop filter, band-rejection filter, band limit filter, T-notch filter, band-elimination filter, and band-reject filter. As defined herein, the notch filter is a filter that passes most frequencies unaltered, but attenuates those in a specific range; which corresponds to the “notch frequency.” As used herein, the notch filter is a band-stop filter with a narrow stopband (high Q factor). As used herein the term “notch” means the range of frequencies which are attenuated.

Notch filters constructed in accordance with the principles of the present invention can be used in many electronic systems such as in live sound reproduction such as PA systems and in instrument amplification, amplifiers or preamplifiers for acoustic instruments such as acoustic guitar, mandolin, bass instrument amplifier, to reduce or prevent feedback, while having little noticeable effect on the rest of the frequency spectrum. The width of the stopband may be less than 1 to 2 decades (i.e., the highest frequency attenuated is less than 10 to 100 times the lowest frequency attenuated), and in connection with audio, a notch filter may be used in connection with high and low frequencies to separate semitones. As a further example, the notch filter may be utilized for eliminating weak spurious signals that need to be removed from weak input signals.

In the following claims, the frame or base may serve as one electrode. In the following claims, the terminology of a notch frequency range is used in the singular but it applies equally well for multiple notch frequencies ranges and should be interpreted so as to encompass both singular and plurality of notch filters, except where specifically noted. The MEMS structure would have to be modified to include multiple frequencies.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the appended claims.

1. A microelectromechanical system (MEMS) notch filter comprising:
a frame;
a plurality of masses that move relative to said frame;
a plurality of resilient members operatively connecting said plurality of masses to said frame; said plurality of movable masses oscillating independently at different resonant frequencies;
a plurality of electrodes operatively connected to said frame comprising at least one input electrode and at least one output electrode;
a plurality of drives operatively connecting said plurality of movable masses to at least one of said plurality of electrodes,
a plurality of switches for selectively connecting the plurality of drives to at least one of the plurality of electrodes; and
each of said plurality of movable masses adapted to oscillate at different resonant frequencies upon application to said input electrode of a voltage having frequency components in a frequency range corresponding to the resonant frequency whereupon current components flowing through the notch filter are attenuated due to energy loss in driving said plurality of movable masses.

2. The MEMS notch filter of claim 1, further comprising a mechanism positioned below said mass, wherein said mechanism is adapted to maintain a position of said mass.

3. The MEMS notch filter of claim 2, wherein said mechanism comprises a fluid dispenser adapted to expel fluid onto said mass.

4. The MEMS notch filter of claim 1, wherein said plurality of drives are comb drives adapted to receive an applied voltage signal from said plurality of electrodes, and wherein a voltage signal is applied to a comb drive at a resonant frequency of one of the plurality of masses mass and the voltage signal induces said mass to oscillate in a geometric plane of said frame.

5. The MEMS notch filter of claim 1, wherein each one of the plurality of masses is approximately 1.4×10⁻³ grams.

6. The MEMS notch filter of claim 1, wherein said resilient members comprise a spring constant of approximately 200 g/s².

7. The MEMS notch filter of claim 1, wherein at least one resonant frequency is approximately between 48 and 62 Hz.

8. A microelectromechanical system (MEMS) device comprising:
a plurality of movable mass components;
at least one resilient member operatively connected to each of said movable mass components;
a plurality of drives operatively connected to each of said movable mass components;
an electrode operatively connected to any of said drive and said movable mass components, said electrode adapted to receive current from an electrical source;
a plurality of switches for selectively connecting the plurality of drives to at least one of the plurality of electrodes;
each of said movable mass components adapted to oscillate independently at a different resonant frequency upon application to said electrode of a current having a plurality of frequency components substantially in a frequency range corresponding to the resonant frequency of the mass, whereupon said current flowing through the MEMS device is attenuated due to energy loss in driving said plurality of movable masses.

9. The MEMS device of claim 8, further comprising a mechanism positioned below said plurality of movable masses, wherein said mechanism is adapted to maintain a neutral position of said mass components.

10. The MEMS device of claim 9, wherein said mechanism comprises a fluid dispenser adapted to expel fluid onto said mass components.

11. The MEMS device of claim 8, wherein oscillation of said mass components causes a dissipation of energy.

12. The MEMS device of claim 8, wherein each of said mass components comprises a mass of approximately 1.4×10⁻³ grams and wherein said resilient members have a spring constant of approximately 200 g/s².

13. The MEMS device of claim 12, wherein one of the resonant frequencies is approximately between 48 and 62 Hz.

14. A method of forming a microelectromechanical system (MEMS) device notch filter, said method comprising:
configuring a plurality of movable proof masses;
operatively connecting at least one resilient member to each of the plurality of movable masses;
operatively connecting one of a plurality of drives to each of the plurality of movable masses; and
utilizing a plurality of switches, operatively connecting a plurality of electrodes to any of one of a plurality of drives and said movable mass,
wherein each of the plurality of movable masses is adapted to oscillate independently at a different resonant frequency with the introduction of an electrical signal on the electrodes having a voltage component in the corresponding frequency range resulting in dissipation of energy and voltage attenuation.

15. The method of claim 14, further comprising positioning a mechanism below each of the plurality of movable masses, wherein said mechanism is adapted to maintain a neutral position of each of the plurality of movable masses.

16. The method of claim 15, wherein said mechanism comprises a fluid dispenser adapted to expel fluid onto said mass.

17. The method of claim 14, wherein each of said drives is an electrostatic comb drive that is adapted to receive an applied voltage signal from said plurality of electrodes, and wherein a voltage signal applied to said electrostatic comb drive at the corresponding resonant frequency induces the corresponding one of the plurality of movable masses to oscillate independently of each other.

18. The method of claim 17, wherein each of the plurality of movable masses comprises a mass of approximately 1.4×10⁻³ grams.

19. The method of claim 17, wherein said at least one resilient member comprises a spring constant of approximately 200 g/s²20.

20. The method of claim 17 wherein one of the resonant frequencies is approximately between 48 and 62 Hz.
